(19) United States
(12) Patent Application Publication
(10) Pub. No.: US 2025/0226304 A1
(43) Pub. Date: Jul. 10, 2025

(54) DEVICE COMPRISING A PLURALITY OF INTEGRATED CIRCUITS AND METHOD OF ASSEMBLING AND ENCAPSULATING INTEGRATED CIRCUITS

(71) Applicant: STMicroelectronics International N.V., Geneva (CH)

(72) Inventor: Romain COFFY, Voiron (FR)

(73) Assignee: STMicroelectronics International N.V., Geneva (CH)

(21) Appl. No.: 19/013,592

(22) Filed: Jan. 8, 2025

(30) Foreign Application Priority Data
Jan. 10, 2024 (FR) FR2400206

(51) Int. Cl. H01L 23/498; H01L 21/56; H01L 21/768; H01L 23/00; H01L 23/31; H01L 25/065

(52) U.S. Cl. CPC H01L 23/49838; H01L 21/56; H01L 21/76877; H01L 23/3121; H01L 23/3135; H01L 25/0657; H01L 23/49866; H01L 24/08; H01L 24/32; H01L 2224/08225; H01L 2224/32145; H01L 2225/06568; H01L 2924/1815

(57) ABSTRACT

A first layer of a resin compatible with a laser direct structuring (LDS) is formed on a substrate and encapsulates a first integrated circuit. The substrate includes a first connection terminal electrically coupled to the first integrated circuit and a second connection terminal covered by the first layer. A first via is formed using LDS, the first via crossing the first layer and forming an electrical connection to the second connection terminal. A second integrated circuit is mounted over the first integrated circuit. A second layer of resin compatible with LDS is formed to encapsulate the second integrated circuit. A second via is formed using LDS, the second via crossing the second layer and forming an electrical connection to the first via.

### PRIORITY CLAIM

This application claims the priority benefit of French Application for U.S. Pat. No. 2,400,206, filed on Jan. 10, 2024, the content of which is hereby incorporated by reference in its entirety to the maximum extent allowable by law.

### TECHNICAL FIELD

The present disclosure generally concerns devices comprising a plurality of integrated circuits and methods of manufacturing such devices.

### BACKGROUND

In microelectronics, the trend is towards miniaturization to consume fewer raw materials and decrease production costs, or to be able to add new functionalities to a product without increasing its size. With this in mind, it is advantageous to stack integrated circuits on a same substrate so that they take up less space. Electrical connections between a first integrated circuit mounted on a substrate can be formed by direct connections between metal pads, and wire bonding offers a solution for forming electrical connections between a second integrated circuit mounted on the first integrated circuit. However, the use of wires requires a significant space around the integrated circuits to be connected.

There thus exists a need for a method of assembling a plurality of circuits stacked on each other on a same substrate, enabling to decrease the dimensions of the final device.

### SUMMARY

An embodiment provides a method comprising: forming on a substrate a first layer of a resin compatible with a direct laser structuring (LDS), wherein a first integrated circuit mounted on the substrate is incorporated (i.e., encapsulated) in the first layer, the substrate comprising a first connection terminal coupled to the first integrated circuit and a second connection terminal coupled to the first connection terminal and covered by the first layer; forming a first via by LDS, the first via crossing the first layer and forming an electrical contact with the second connection terminal; mounting a second integrated circuit on the first integrated circuit; forming on the substrate a second layer of the LDS-compatible resin, wherein the second integrated circuit is incorporated (i.e., encapsulated) in the second layer; and forming a second via by LDS crossing the second layer and forming an electrical contact with the first via.

According to an embodiment, forming the first layer comprises depositing an initial resin layer and thinning the initial resin layer to obtain the first layer.

According to an embodiment, forming the second layer comprises depositing an initial resin layer and thinning of the initial resin layer to obtain the second layer.

According to an embodiment, the method further comprises adding a device on the second layer, the device being coupled to the second via.

According to an embodiment, the method further comprises depositing a third layer made of resin on the second layer.

According to an embodiment, the first integrated circuit and the second integrated circuit each have a first surface comprising metallizations comprising one or a plurality of connection terminals and a second surface opposite to the first surface, the first and second integrated circuits being mounted with their second surfaces facing each other.

According to an embodiment, the vias are formed by autocatalytic growth or electroless plating.

According to an embodiment, the second via is laterally offset with respect to the first via.

According to an embodiment, the height of the first layer is at least equal to the distance separating the second connection terminal from the upper surface of the first integrated circuit.

According to an embodiment, the height of the second layer is at least equal to the distance separating the first via from the upper surface of the second integrated circuit.

Another embodiment provides a microelectronic device comprising: a substrate; a first integrated circuit mounted on the substrate; a first layer of a resin, compatible with a direct laser structuring (LDS) deposited on the substrate and having the first integrated circuit incorporated (i.e., encapsulated) therein; in the substrate, a first connection terminal coupled to the first integrated circuit and a second connection terminal coupled to the first connection terminal and covered by the first layer; a first via formed by LDS, the first via crossing the first layer and forming an electrical contact with the second connection terminal; a second integrated circuit mounted on the first integrated circuit; a second layer of the LDS-compatible resin, the second integrated circuit being incorporated (i.e., encapsulated) in the second layer; and a second via formed by LDS crossing the second layer and forming an electrical contact with the first via.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a cross-section view of a device comprising two integrated circuits connected to each other and to a same substrate according to an embodiment of the present disclosure;

FIGS. 2A to 2I are cross-section views of successive steps of a method of manufacturing the device of FIG. 1, according to an embodiment of the present disclosure;

FIGS. 3A and 3B are cross-section views of successive steps of a manufacturing method capable of applying to the device of FIG. 1; and

FIGS. 4A and 4B show partial cross-section views of the successive steps of a method of panel-embedded packaging (PEP) of an integrated circuit.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the steps of manufacturing of a laminated substrate and of the integrated circuits are usual and are not detailed.

Unless indicated otherwise, when reference is made to two elements connected together, this signifies a direct connection without any intermediate elements other than conductors, and when reference is made to two elements coupled together, this signifies that these two elements can be connected or they can be coupled using one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

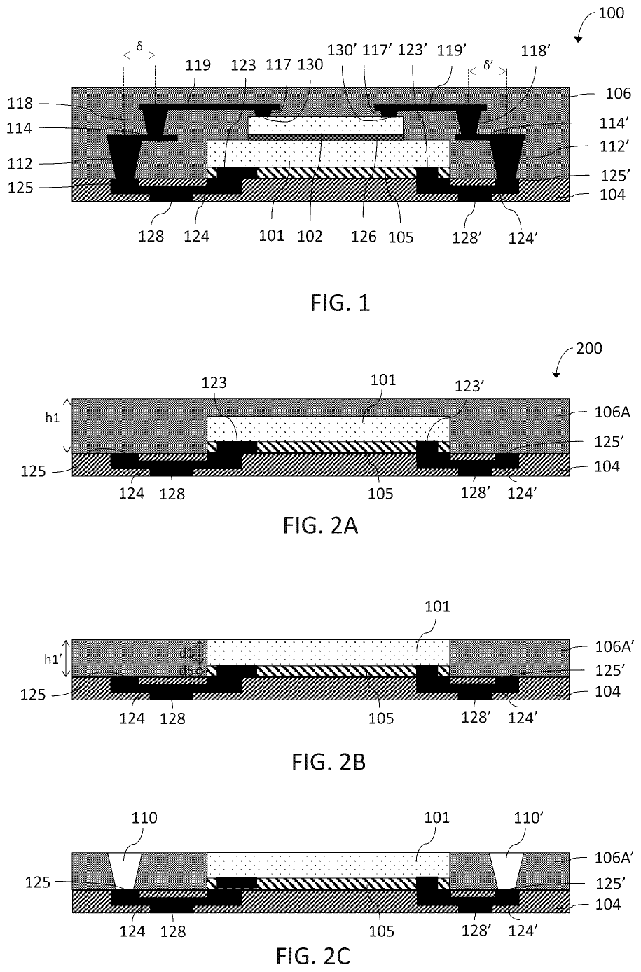

FIG. 1 is a cross-section view of a device 100 comprising two integrated circuits 101, 102 connected to each other and to a same substrate 104 according to an embodiment of the present disclosure.

In the example of FIG. 1, the two integrated circuits 101 and 102 are mounted one on top of the other using a bonding layer 126 and encapsulated in a resin 106. Integrated circuit 101 is, for example, mounted on substrate 104 using a dielectric layer 105. Integrated circuits 101 and 102 are electrically connected to each other and to substrate 104 by a set of vias 112, 117, 118, 112′, 117′, 118′ and metal tracks 114, 119, 124, 114′, 119′, 124′ formed in resin 106, in substrate 104, and/or in dielectric layer 105.

Substrate 104 and dielectric layer 105 are, for example, made of Ajinomoto Build-up Film (ABF) or, for example, of polymer. Substrate 104 has a thickness, for example, at least equal to 50 μm. Dielectric layer 105 has a thickness, for example, at least equal to 10 μm.

Integrated circuits 101 and 102 each have metallizations comprising one or a plurality of connection terminals 123, 130, 123′, 130′ on a first surface of each of integrated circuits 101, 102, and have, for example, no metallization or connection terminal on a second surface opposite to the first surface. The second integrated circuit 102 is mounted on the first integrated circuit 101 so that the second surfaces of the circuits 101 and 102 face each other and so that the connection terminals present on their first surfaces remain accessible.

The connection terminal 123 of integrated circuit 101 is, for example, on its lower surface, and is, for example, connected by one or a plurality of metal tracks 124 to a connection terminal 125 on the upper surface of substrate 104. Metal tracks 124 are, for example, made of copper, of gold, of tin, of silver, or of an alloy of a plurality of these materials.

In certain embodiments, connection terminals 123 and 125 are also connected using metal tracks 124 to a connection terminal 128 enabling to couple device 100 to an external electronic device, not shown. Connection terminal 128 is. for example. present on the lower surface of substrate 104.

The connection terminal 130 of integrated circuit 102 is, for example, on its upper surface. Connection terminals 125 and 130 are connected to each other using via 112 and via 118. In the example of FIG. 1, via 112 has a height at least equal to the sum of the height of the first integrated circuit 101 and of the height of dielectric layer 105. In the general case, via 112 has a height at least equal to the distance separating connection terminal 125 from the upper surface of integrated circuit 101. In the example shown in FIG. 1, the height of via 118 is at least equal to the sum of the height of the second integrated circuit 102 and of the height of bonding layer 126. In the general case, via 118 has a height at least equal to the distance separating via 112 from the upper surface of integrated circuit 102.

According to an embodiment, vias 112 and 118 are laterally offset, that is, offset in a direction parallel to the plane of substrate 104, from each other by a distance 8. Vias 112 and 118 are, for example, connected to each other using metal track 114.

A via 117 is connected, on the one hand, to the connection terminal 130 of integrated circuit 102 and, on the other hand, to via 118 using one or a plurality of metal tracks 119.

The resin 106 used to encapsulate integrated circuit 101 is, for example, a specific resin compatible with a direct laser structuring (LDS) in that it includes additives or particles which can be activated by laser processing at locations where vias and tracks are desired. The thickness of resin layer 106 is, for example, at least equal to the sum of the heights of vias 112 and 118. In the example of FIG. 1, the thickness of resin layer 106 is sufficient to cover metal tracks 119.

In the example of FIG. 1, a second set of connection terminals 123′, 125′, 128′, and 130′ as well as of vias 112′, 117′, 118′ and metal tracks 114′, 119′, 124′ is shown and is similar to that described hereabove and will not be described in detail. In other embodiments, it would be possible to provide a single set, or more than two sets, of connection terminals, of vias, and of metal tracks.

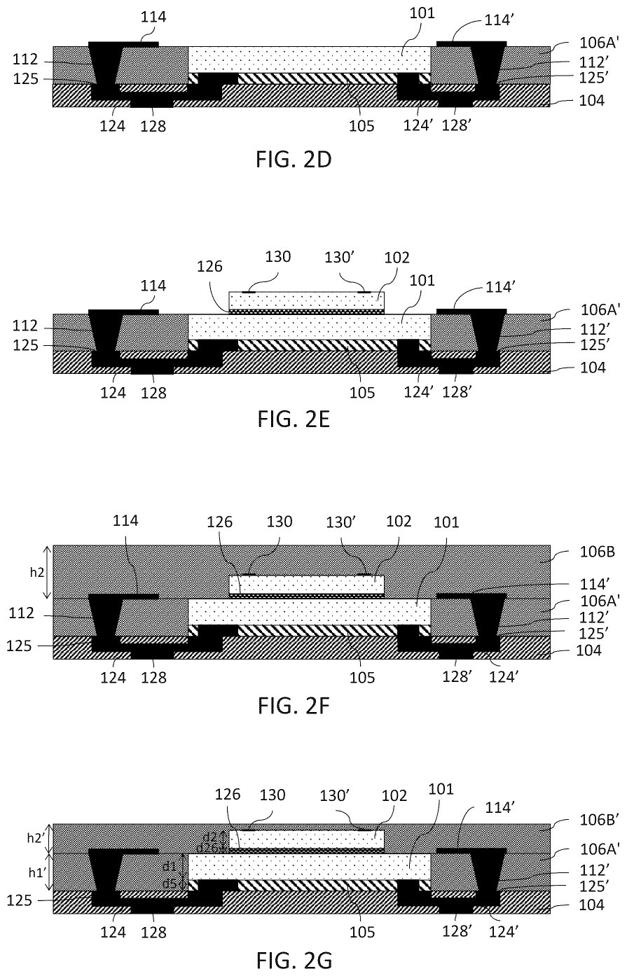

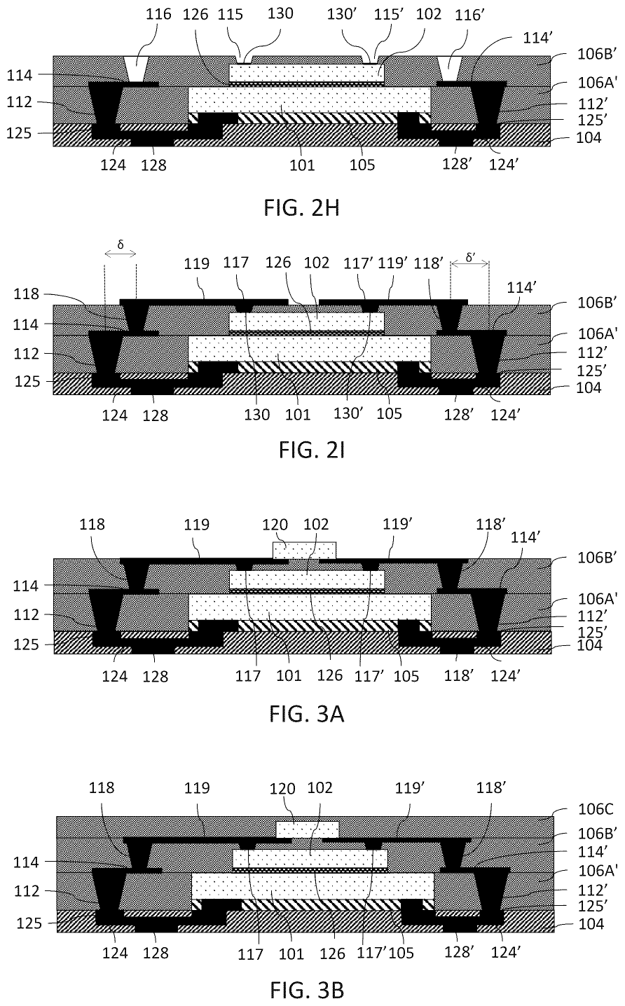

FIGS. 2A to 2I are cross-section views of successive steps of a method of manufacturing the device 100 of FIG. 1 according to an embodiment of the present disclosure.

Certain elements of FIGS. 2A to 2I are identical to elements of FIG. 1, and these elements are designated with the same references and are not described again in detail.

In the following description of FIGS. 2A to 2I, only the forming of metal tracks 114 and 119 and of vias 112, 117, and 118 is described, the same steps are, for example, used for the forming of metal tracks 114′ and 119′ and of vias 112′, 117′, and 118′.

FIG. 2A shows an example of a device 200 providing a starting point for the method of manufacturing the device 100 of FIG. 1. As compared with the device 100 of FIG. 1, device 200 does not comprise yet the second integrated circuit 102 or the vias 112, 118 for connecting circuits 101 and 102 to each other and to substrate 104.

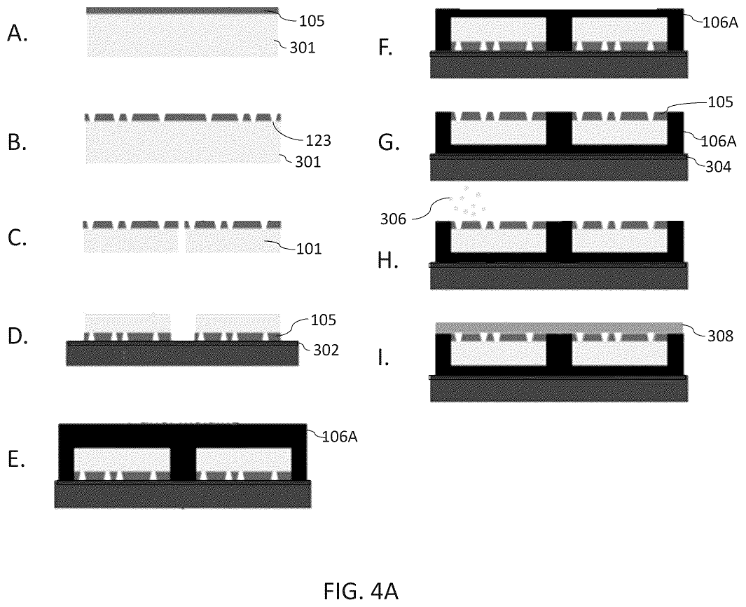

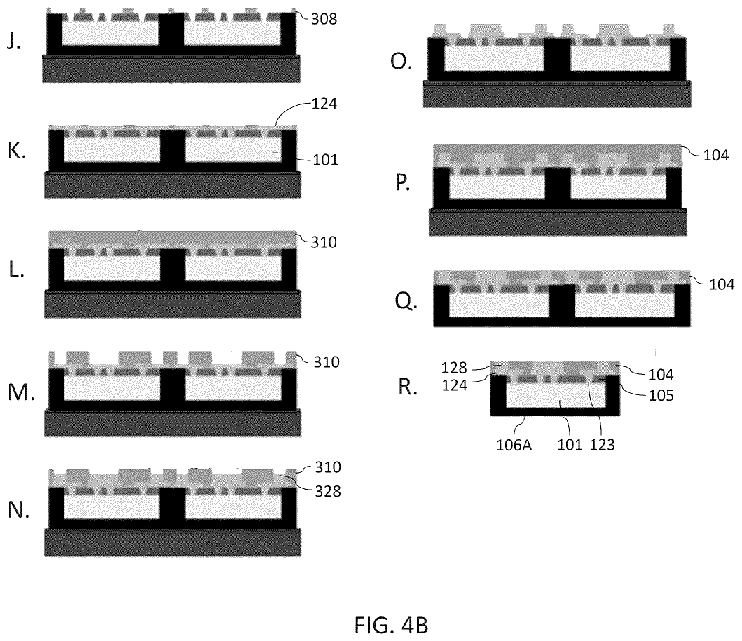

The device 200 of FIG. 2A is, for example, obtained according to manufacturing steps of a panel-embedded packaging (PEP) method detailed in FIGS. 4A and 4B.

Device 200, in the example of FIG. 2A, comprises the first integrated circuit 101, in flip-chip orientation with the connection terminals 123, 123′ at the front side facing and connected to substrate 104, encapsulated in a resin layer 106A. The height h1 of resin layer 106A is, for example, sufficient to cover integrated circuit 101 and connection terminal 125.

FIG. 2B shows the device of FIG. 2A after an optional step of thinning of resin layer 106A. According to an embodiment, the thickness of the resin layer is decreased to expose the back side of the integrated circuit 101. This step is useful, for example, in anticipation of the bonding of a second integrated circuit 102 to the first integrated circuit 101.

The final height h1′ of resin layer 106A′ is, in the example of FIG. 2B, at least equal to the sum of the height d1 of the first integrated circuit 101 and of the height d5 of dielectric layer 105. In the general case, height h1′ is, for example, at least equal to the distance separating connection terminal 125 from the upper surface of integrated circuit 101.

In the following description of FIGS. 2C to 2K, it is considered that the steps are applied to the device obtained at the step of FIG. 2B. However, in the case where the step of FIG. 2B is omitted, it will be clear to those skilled in the art how the steps in FIGS. 2C to 2K would be adapted.

FIG. 2C shows the device of FIG. 2B after a laser ablation (or drilling) step. Resin layer 106A′ is perforated by a laser beam to partially expose the connection terminals 125 present on the surface of substrate 104. The performed perforations 110 correspond to the locations of future metal vias.

During the laser ablation step, the laser beam used to perforate resin 106A′ interacts with LDS additives present in resin 106A′ and locally activates the periphery of perforations 110.

Further, the locations of future formations of the metal tracks 114, on the upper surface of resin 106A′, that is, the surface most distant from substrate 104, are for example illuminated by the laser beam during this step in order to locally activate them.

FIG. 2D illustrates the device of FIG. 2C, for example, after a step of autocatalytic growth or electroless plating. During this method, a metal is deposited, without using an electric current, on the surfaces of resin 106A′ previously activated by a laser beam. The activation of the resin by the laser beam creates a seed on the resin surface, at the locations where it has been illuminated. For example, vias 112 are created in the perforations 110 of FIG. 2C, starting from the exposed connection terminals 125 and the previously-activated periphery of perforations 110. Metal tracks 114 are, for example, created on the surface of resin 106A′, on the previously-activated portions.

Although FIG. 2D shows an example of electroless plating to form metal tracks 114 and vias 112, it would also be possible to use an electroplating method. In this case, temporary metal tracks (not shown) are, for example, created on the surface of resin layer 106A′ to circulate an electric current used to achieve this electroplating.

Vias 112 are, for example, made of copper, of gold, of tin, of silver, or of an alloy of a plurality of these materials.

The steps described hereabove in relation with FIGS. 2C and 2D correspond to an implementation of an LDS method.

FIG. 2E illustrates the device of FIG. 2D after the bonding of the second integrated circuit 102 to the first integrated circuit 101. As described in relation with FIG. 1, integrated circuits 101 and 102 each comprise a first (or front side) surface comprising metallizations comprising one or a plurality of connection terminals and a second (or back side) surface, opposite to the first surface, which for example comprises no metallizations or connection terminal. The second integrated circuit 102 is for example bonded so that the second surfaces of the two integrated circuits 101 and 102 are in contact and its connection terminals are located on its upper surface so that they remain accessible after the bonding. The two integrated circuits are, for example, bonded by using an epoxy-based glue which polymerizes during a heating step.

According to an embodiment, in the case where the thinning step of FIG. 2B is omitted or a partial thinning is performed, a resin layer is present between integrated circuits 101 and 102.

FIG. 2F shows the device of FIG. 2E after the deposition of a second layer of resin 106B compatible with LDS.

The deposition of resin layer 106B is, for example, performed by compression molding, the resin being for example deposited on the surface of the device of FIG. 2E and pressed into a mold.

The thickness h2 of layer 106B is, for example, at least equal to the height of the future vias 118, that is, for example, at least sufficient to cover integrated circuit 102.

FIG. 2G shows the device of FIG. 2F after an optional step of thinning of resin layer 106B.

As for height h2, the final height h2′ of resin layer 106B′ is, in the example shown in FIG. 2G, at least equal to the sum of the height d2 of the second integrated circuit 102 and of the height d26 of bonding layer 126. In the general case, height h2′ is, for example, greater than the distance separating via 112 from the upper surface of integrated circuit 102 to cover integrated circuit 102.

In the following description of FIGS. 2H to 2K, it is considered that the steps are applied to the device obtained at the step of FIG. 2G. However, in the case where the step of FIG. 2G is omitted, it would be clear to those skilled in the art how the steps in FIGS. 2H to 2K would be adapted.

FIG. 2H shows the device of FIG. 2G after a laser ablation (or drilling) step. Resin layer 106B is perforated by a laser beam to form perforations 116 and for example perforations 115, which correspond to the locations of future vias. Perforations 116 expose at least a portion of the metal tracks 114 which are coupled to the at least one connection terminal 123 of integrated circuit 101 and to the at least one connection terminal 128 of substrate 104. Perforations 115 expose, for example, connection terminals 130 of integrated circuit 102.

After the laser ablation step, the periphery of perforations 115, 116 is activated.

Further, the locations of future formations of metal tracks 119, on the upper surface of resin 106B′, are illuminated, for example, by the laser beam during this step to locally activate them.

FIG. 2I shows the device of FIG. 2H, for example, after an autocatalytic growth step. During this method, vias 118 are created in the perforations 116 of FIG. 2H, starting from the exposed portions of metal tracks 114 and from the previously-activated periphery of perforations 116. Vias 117 are, for example, created in the perforations 115 of FIG. 2H, starting from the exposed connection terminals of integrated circuit 102 and from the previously-activated periphery of perforations 115. Metal tracks 119 are, for example, created on the surface of resin 106B, on the previously-activated portions. Vias 118, 117 and tracks 119 are, for example, made of copper, of gold, of tin, of silver, or of an alloy of a plurality of these materials.

The steps described above in relation with FIGS. 2H and 2I correspond to an implementation of an LDS method. The LDS method is only possible on compatible resin layers.

According to an embodiment, the vias formed by autocatalytic growth at steps 2C and 2H are created by forming a metal layer on the walls of perforations 110, 116, 115. The vias 112, 118, 117 thus created form, for example, cones partially filled at their center. Vias 112 and 118 are, for example, offset from one another by a distance 8 and connected by metal tracks 114 to ensure a good connection.

Although FIG. 2I shows an example of electroless plating to form metal tracks 119 and vias 114, it would also be possible to use an electroplating method. In this case, for example, temporary metal tracks (not shown) are created on the surface of resin layer 106B′ to circulate an electric current used to obtain this electroplating.

After a step of deposition of a third resin layer on the surface of the device of FIG. 2I, not shown, the device 100 of FIG. 1 is obtained. The assembly formed by resin layers 106A′, 106B′ and the third resin layer corresponds to the resin layer 106 of FIG. 1.

FIG. 3A and FIG. 3B are cross-section views of successive steps of a manufacturing method that can apply to the device of FIG. 1.

Certain elements of FIGS. 3A and 3B are identical to elements of FIGS. 1 and/or FIGS. 2A to 2I, and these elements are designated with the same references and are not described again in detail.

FIG. 3A shows the device of FIG. 2I after an optional step of connection of a surface-mount device (SMD) 120 to metal tracks 119 and 119′. According to an embodiment, surface-mount component 120 is, for example, added to the device 100 of FIG. 1, and is integrated during the encapsulation method. Component 120 is for example soldered or bonded with a conductive glue between tracks 119 and 119′.

FIG. 3B shows the device of FIG. 3A after an optional step of deposition of a resin layer 106C to encapsulate component 120. A resin which is not LDS-compatible is, for example, used for this layer. The height of resin layer 106C is, for example, at least as high as component 120 and, for example, higher than component 120 to cover it in order to protect it and to insulate it.

According to an embodiment alternative to that shown in FIG. 3B, a succession of layers, for example comprising nickel and/or gold layers, is deposited, for example, by electroplating on the surface of metal tracks 119 to make them corrosion-resistant, and no resin layer 106C is deposited.

In the example of FIG. 1, FIGS. 2A to 2I, and FIGS. 3A and 3B, a dielectric layer 105 is present between substrate 104 and chip 101. However, in other embodiments, layer 105 is omitted, and integrated circuit 101 is directly mounted on substrate 104. It would be clear to those skilled in the art how the processes would be adapted.

During the method thus described, two series of vias 112 and 118 are successively created. An advantage of creating these two series of vias instead of a single via is that the height of each via is decreased, making the final device more compact. Indeed, the aspect ratio of a via is generally limited. For example, in the case of a via formed by LDS, the aspect ratio is limited to 1:1, that is, the height cannot exceed the diameter of the via. Creating two successive vias thus takes up less surface area than creating a single via which is higher and thus wider. For example, when it is desired to form a 300-μm high via, it is possible to create two vias having a 150-μm height and a 150-μm maximum diameter one above the other, for a total 300-μm height and a maximum 150-μm diameter, if the aspect ratio is limited to 1. For comparison, a single 300-μm high via would require a 300-μm maximum diameter. The surface area required for the vias is thus effectively decreased.

FIG. 4A and FIG. 4B show partial cross-section views of the successive steps of a method of panel-embedded packaging (PEP) of an integrated circuit 101.

Elements of FIGS. 4A and 4B are identical to elements of FIGS. 1 and/or 2A to 2I and/or 3A to 3B, are designated with the same references and are not detailed again.

The PEP encapsulation process is for example used to obtain the device 200 of FIG. 2A.

At a step A, a substrate, for example a wafer 301 of a semiconductor material, for example silicon, comprising integrated circuits (not illustrated at step A) is covered with dielectric layer 105. Dielectric layer 105 is, for example, an ABF or polymer film.

At a step B, after the deposition of dielectric layer 105, layer 105 is, for example, locally opened by laser and/or plasma etching to create perforations for example at the location of the connection terminal 123 of the integrated circuit 101 of FIGS. 1, 2A to 2I, and 3A to 3B present on wafer 301. The perforations will be used to form conductive vias.

At a step C, the wafer 301 of step B is then, for example, ground to remove a substrate thickness useless for the operation of the integrated circuits, and diced to separate integrated circuits 101 into individual electronic chips.

At a step D, following step C, the electronic chips are turned over and repositioned on a support board made, for example, of stainless steel, so that dielectric layer 105 is bonded to the board by a temporary bonding film 302.

At a step E, following step D, the chips are then, for example, spaced apart, the spacing between chips being sufficient, for example, for the creation of the future vias 112 of FIG. 2D. The support board is for example rectangular and is, for example, larger than a silicon wafer, for example 700 mm by 700 mm. Resin layer 106A is deposited to encapsulate the chips.

At a step F, after the deposition of resin layer 106A, it is for example thinned by abrasive polishing.

At a step G, following step F, the chips encapsulated in resin 106A are separated from the support board, turned over to expose dielectric layer 105, and their opposite surface is bonded to the support board by a temporary bonding film 304. An automatic optical inspection (AOI) is, for example, carried out to detect defects on the chips.

At a step H, following step G, metal particles 306, for example of copper and titanium, are deposited on the surface of the encapsulated chips. These particles will be used as seeds for a subsequent autocatalytic or electrocatalytic growth step.

At a step I, after the deposition of metal particles 306, a photoresist layer 308 is for example deposited.

At a step J, after the deposition of layer 308, it is exposed by laser direct imaging (LDI) and developed to create openings in the dielectric layer. The use of a laser rather than of a mask for this photolithography step allows an adjustment of the illumination pattern of the dielectric layer. The position of the electronic chips on the support board may vary from one board to another, and the LDI imaging enables to adapt to the variations.

At a step K, after the forming of openings, metal vias and tracks 124 are formed, for example, by electroplating.

At a step L, after the forming of metal tracks 124, a photoresist layer 310 is, for example, deposited.

At a step M, layer 310 is exposed by LDI and developed to create openings in photoresist layer 310.

At a step N, following step M, metal tracks 128, for example made of copper, are created on the metal tracks deposited at step K, for example by electroplating according to the openings in layer 310. Tracks 128 form, for example, connection terminals.

At a step O, following step N, layers 308 and 310 as well as the precursor particles 306 remaining under layers 308 and 310 are removed, for example by etching.

At a step P, after the etching step, a dielectric layer 104 is deposited to encapsulate the metal tracks and vias.

At a step Q, after the deposition of dielectric layer 104, it is for example thinned to expose metal tracks 328, and a succession of layers, for example comprising nickel and/or gold layers, is for example deposited by electroplating at the surface of metal tracks 328 to make them corrosion-resistant. The structure comprising two integrated circuits 101 is separated from the support board.

The method described by the steps A to Q detailed in relation with FIGS. 4A and 4B is for example used to encapsulate integrated circuit 101 and obtain the device 200 of FIG. 2A. The resin used to coat the integrated circuits is then, for example, a specific resin compatible with LDS. In the example of FIGS. 4A and 4B, a structure comprising two integrated circuits 101 is formed. In other embodiments, a structure comprising one or more than two integrated circuits 101 side-by-side may be formed by the same method. The method described in relation with FIGS. 2A to 2I is, for example, simultaneously applied to all integrated circuits 101, and a plurality of individual devices 100 are obtained by separating the structure, for example by laser cutting or mechanical sawing.

As a variant, after step Q, at a step R, the electronic chips are for example separated into individual electronic chips, for example by laser cutting or mechanical sawing. In this case, the method described in relation with FIGS. 2A to 2I is applied to each electronic chip individually.

Various embodiments and variants have been described. Those skilled in the art will understand that certain features of these various embodiments and variants may be combined, and other variants will occur to those skilled in the art. In particular, the method described in FIGS. 2A to 2I is illustrated for a single device 100, but it could be carried out for a plurality of devices simultaneously, bonded to a common substrate and separated at the end of the method. The method is detailed for two integrated circuits 101 and 102 but may be extended to a stack of at least three integrated circuits, in which case a set of vias is for example formed for each integrated circuit. Further, although an example of the forming of the device 200 of FIG. 2A has been detailed in relation with the methods of FIGS. 4A and 4B, other methods could be used to obtain this device.

1. A method, comprising:
forming on a substrate a first layer of a resin compatible with laser direct structuring (LDS), wherein a first integrated circuit is mounted on the substrate and incorporated in the first layer, the substrate comprising a first connection terminal electrically coupled to the first integrated circuit and a second connection terminal electrically coupled to the first connection terminal and covered by the first layer;
forming by LDS processing a first via that crosses through the first layer and forms an electrical coupling to the second connection terminal;
mounting a second integrated circuit over the first integrated circuit;
forming a second layer of the resin compatible with LDS on the first layer, wherein the second integrated circuit is incorporated in the second layer; and
forming by LDS processing a second via that crosses through the second layer and forms an electrical coupling to the first via.

2. The method according to claim 1, wherein forming the first layer comprises depositing an initial resin layer having a first thickness and thinning the initial resin layer to obtain the first layer having a second thickness less than the first thickness.

3. The method according to claim 2, wherein forming the second layer comprises depositing a further initial resin layer having a third thickness and thinning the further initial resin layer to obtain the second layer having a fourth thickness less than the third thickness.

4. The method according to claim 1, further comprising the adding a device on top of an upper surface of the second layer, wherein the device is electrically coupled to the second via.

5. The method according to claim 1, further comprising depositing a third layer made of resin on the second layer.

6. The method according to claim 1, wherein the first integrated circuit and the second integrated circuit each have a first surface comprising metallizations comprising one or a plurality of connection terminals and a second surface opposite to the first surface, and wherein the first and second integrated circuits are mounted with their second surfaces facing each other.

7. The method according to claim 1, wherein the first and second vias are formed in the LDS processing by one of: autocatalytic growth or electroless plating.

8. The method according to claim 1, wherein the second via is laterally offset with respect to the first via and connected to each other by a conductive track.

9. The method according to claim 1, wherein a height of the first layer is at least equal to a distance separating the second connection terminal from an upper surface of the first integrated circuit.

10. The method according to claim 1, wherein a height of the second layer is at least equal to a distance separating the first via from an upper surface of the second integrated circuit.

11. A microelectronic device, comprising:
a substrate including a first connection terminal and a second connection terminal electrically coupled to the first connection terminal;
a first integrated circuit mounted on the substrate and electrically coupled to the first connection terminal;
a first layer of a resin compatible with laser direct structuring (LDS) on the substrate, wherein the first integrated circuit is incorporated in the first layer and the first layer covers the second connection terminal;
a first LDS via crossing through the first layer and electrically coupled to the second connection terminal;
a second integrated circuit mounted over the first integrated circuit;
a second layer of resin compatible with LDS on the first layer, wherein the second integrated circuit is incorporated in the second layer; and
a second LDS via crossing through the second layer and electrically coupled to the first LDS via.

12. The device according to claim 11, further comprising an LDS metal track which electrically couples the second LDS via to the second integrated circuit.

13. The device according to claim 11, wherein the second LDS via is laterally offset with respect to the first LDS via and connected thereto by an LDS metal track.

14. The device according to claim 11, wherein the first integrated circuit and the second integrated circuit each have a first surface comprising metallizations comprising one or a plurality of connection terminals and a second surface opposite to the first surface, and wherein the first and second integrated circuits are mounted with their second surfaces facing each other.

15. The device according to claim 11, further comprising a device on the second layer, wherein the device is electrically coupled to the second via.

16. The device according to claim 11, further comprising a third layer made of resin on the second layer and covering the second LDS via.
